(19) United States
(12) Patent Application Publication
(10) Pub. No.: US 2023/0397377 A1
(43) Pub. Date: Dec. 7, 2023

(54) CLASSIFIED HEAT DISSIPATION SYSTEM AND DATA CENTER

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Shuqin FENG, Zhangjiakou City (CN)

(21) Appl. No.: 18/205,575

(22) Filed: Jun. 5, 2023

(30) Foreign Application Priority Data
Jun. 6, 2022 (CN) 202210633817.7

(51) Int. Cl. H05K 7/20

(52) U.S. Cl. CPC H05K 7/2079; H05K 7/20745

(57) ABSTRACT

The present disclosure discloses a classified heat dissipation system including an accommodating area, a group to be heat dissipated, an air cooling device, and a liquid cooling device. A top end of the accommodating area is provided with a thermal sandwich channel. The group to be heat dissipated is installed in the accommodating area, the group to be heat dissipated includes at least two device groups, a thermal channel is surrounded between the at least two device groups, and the thermal channel is communicated with the thermal sandwich channel, where each of the at least two device groups has rest of heating sources and a plurality of primary heating sources. The air cooling device conveys cold air into the accommodating area, and the cold air enters the thermal sandwich channel through the device group and the thermal channel. The liquid cooling device is in contact with the primary heating sources.

### CROSS-REFERENCE TO RELATED APPLICATION

This application claims priority to Chinese Patent Application No. 202210633817.7, titled “CLASSIFIED HEAT DISSIPATION SYSTEM AND DATA CENTER” and filed to the China National Intellectual Property Administration on Jun. 6, 2022, the entire contents of which are incorporated herein by reference.

### TECHNICAL FIELD

The present disclosure relates to the field of data centers, and more particularly, to a classified heat dissipation system and a data center.

### BACKGROUND

In recent years, with the rapid development of data center related technologies, centralized configuration of computer room servers, together with servers and storage systems, has changed, and their power density and heat density have increased rapidly, resulting in a surge in heat generated by data centers, which leads to higher and higher requirements of the data centers for refrigeration systems.

In existing refrigeration modes of the data centers, generally air-cooled air conditioners or liquid-cooled heat dissipation systems are separately used. However, there are different heating sources in the servers of the data centers, and refrigerating capacity required by each heating source is not consistent. Therefore, if a single air-cooled air conditioner is used for air cooling, all the heating sources of the servers of the data centers cannot be effectively refrigerated. However, if single liquid cooling refrigeration is adopted, manufacturing costs will increase exponentially, leading to higher manufacturing costs and making it inconvenient for subsequent maintenance.

### SUMMARY

An objective of the present disclosure is to provide a classified heat dissipation system and a data center, which can carry out classified heat dissipation according to heat dissipation requirements to meet the heat dissipation requirements.

To achieve the above objective, one aspect of the present disclosure provides a classified heat dissipation system, which at least includes an accommodating area, a group to be heat dissipated, an air cooling device and a liquid cooling device, where a top end of the accommodating area is provided with a thermal sandwich channel. The group to be heat dissipated is installed in the accommodating area, the group to be heat dissipated includes at least two device groups, a thermal channel is surrounded between the at least two device groups, and the thermal channel is communicated with the thermal sandwich channel, where each of the at least two device groups has rest of heating sources and a plurality of primary heating sources. The air cooling device conveys cold air into the accommodating area, and the cold air enters the thermal sandwich channel through the device group and the thermal channel to dissipate heat from the primary heating sources and the rest of heating sources. The liquid cooling device is in contact with the primary heating sources to dissipate heat from the primary heating sources.

As a further improvement of the technical solutions, number of the device groups is two, and the two device groups are arranged in parallel at intervals. The group to be heat dissipated further comprises two sealing plates, where the two sealing plates are respectively positioned at two ends spaced between the two device groups, and the two sealing plates and the two device groups surround to form the thermal channel.

As a further improvement of the technical solutions, the air cooling device is connected to one side of the accommodating area, there are a plurality of the air cooling devices, and the plurality of air cooling devices are arranged at intervals along a length direction of the accommodating area.

As a further improvement of the technical solutions, there are a plurality of the groups to be heat dissipated, and the plurality of groups to be heat dissipated are arranged at intervals along the length direction of the accommodating area.

As a further improvement of the technical solutions, the liquid cooling device comprises a first circulation loop and a plurality of heat conductive components. A cooling tower is connected in series with the first circulation loop, and the cooling tower is configured to exchange heat with liquid in the first circulation loop. One end of each of the plurality of heat conductive components is connected in series with the first circulation loop, and the plurality of heat conductive components are connected in parallel with each other. Other ends of the plurality of heat conductive components are respectively in contact with the plurality of primary heating sources, to exchange heat from the plurality of primary heating sources with the liquid in the first circulation loop through the plurality of heat conductive components.

As a further improvement of the technical solutions, the liquid cooling device comprises an external circulation loop, an internal circulation loop, a heat exchange unit, and a plurality of heat conductive components. An outer flow passage of the heat exchange unit is connected in series with the external circulation loop, an inner flow passage of the heat exchange unit is connected in series with the internal circulation loop, and a cooling tower is connected in series with the external circulation loop, such that liquid in the external circulation loop exchanges heat with liquid in the internal circulation loop. One end of each of the plurality of heat conductive components is connected in series with the internal circulation loop, and the plurality of heat conductive components are connected in parallel with each other. Other ends of the plurality of heat conductive components are respectively in contact with the plurality of primary heating sources, to exchange heat from the plurality of primary heating sources with the liquid in the internal circulation loop through the plurality of heat conductive components.

As a further improvement of the technical solutions, the heat conductive component comprises a heat exchange box, a male contact head, and a female contact head. The male contact head is connected to the heat exchange box, and one end of the male contact head is positioned in an internal cavity of the heat exchange box. One end of the female contact head is detachably connected to other end of the male contact head, and other end of the female contact head is in contact with the primary heating source. Circulating liquid in the internal circulation loop flows through the internal cavity of the heat exchange box and exchanges heat with the primary heating source through the male contact head and the female contact head.

As a further improvement of the above technical solutions, the other end of the female contact head is provided with a plurality of heat conductive bars, and the plurality of heat conductive bars are respectively connected to the plurality of primary heating sources.

To achieve the above objective, another aspect of the present disclosure also provides a data center, which at least includes a plurality of computer rooms, each of the plurality of computer rooms is provided with the classified heat dissipation system described above, where the accommodation area is the computer room.

As a further improvement of the technical solutions, the device group comprises an array cabinet and a plurality of servers. The plurality of servers are arranged side by side, and the array cabinet and the heat exchange unit are respectively positioned at two ends of each of the plurality of servers.

Thus, according to the technical solutions provided by the present disclosure, a group to be heat dissipated is arranged in the accommodating area, where the group to be heat dissipated comprises a plurality of device groups, and the plurality of device groups can surround and form a thermal channel. The thermal channel is communicated with the thermal sandwich channel positioned at the top end of the accommodating area. When the air cooling device blows cold air into the accommodating area to dissipate heat, gas in the accommodating area may flow out through the device group, the thermal channel and the thermal sandwich channel in turn, thus exchanging heat through the plurality of device groups. Meanwhile, the heating sources above the device group are classified into the primary heating sources and rest of heating sources according to calorific capacity, and the liquid cooling device is in contact with the primary heating sources, to carry out liquid cooling and dissipate heat from the primary heating sources. In this way, liquid cooling and air cooling are selected for heat dissipation or only the air cooling is selected for heat dissipation according to heat dissipation requirements of each heating source above the device group, to implement classified heat dissipation and effectively meet the heat dissipation requirements.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a classified heat dissipation system according to an embodiment provided by the present disclosure;

FIG. 2 is an A-A schematic sectional view of FIG. 1;

FIG. 3 is a schematic diagram showing a partial structure of FIG. 1; and

FIG. 4 is a schematic diagram showing connection between an internal circulation loop and a primary heating source according to an embodiment provided by the present disclosure.

Reference numerals in the figures: accommodation area 1; thermal sandwich channel 11; group to be heat dissipated 2; device group 21; array cabinet 211; server 212; thermal channel 22; sealing plate 23; air cooling device 3; liquid cooling device 4; external circulation loop 41; internal circulation loop 42; heat exchange unit 43; heat conductive component 5; heat exchange box 51; male contact head 52; female contact head 53; and heat conductive bar 531.

### DETAILED DESCRIPTION

Detailed description of implementations of the present disclosure will further be made below with reference to drawings to make the above objectives, technical solutions and advantages of the present disclosure more apparent. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

In existing refrigeration modes of the data centers, generally air-cooled air conditioners or liquid-cooled heat dissipation systems are separately used.

However, there are different heating sources in the servers of the data centers, and refrigerating capacity required by each heating source is not consistent. Therefore, if a single air-cooled air conditioner is used for air cooling, all the heating sources of the servers of the data centers cannot be effectively refrigerated, which has an adverse effect on refrigeration effects. However, if single liquid cooling refrigeration is adopted, manufacturing costs will increase exponentially, leading to higher manufacturing costs and making it inconvenient for subsequent maintenance. Therefore, there is an urgent need for a classified heat dissipation system and a data center, which can carry out classified heat dissipation according to heat dissipation requirements to meet the heat dissipation requirements.

The technical solutions in the embodiment of the present disclosure will be clearly and completely described with reference to the accompanying drawings. Apparently, the embodiments described in the present disclosure are some but not all of the embodiments of the present disclosure. All other embodiments obtained by a person of ordinary skill in the art based on the embodiments of the present disclosure without creative efforts shall fall within the protection scope of the present disclosure.

The present disclosure provides a classified heat dissipation system, which can be applied to a data center to dissipate heat from an array cabinet and a server in the data center. Technicians can classify the heating sources into primary heating sources and rest of heating sources according to calorific capacity of main heating sources in the server and the array cabinet and according to a preset threshold (set by the technicians based on experiences). Specifically, when the calorific capacity of a heating source is greater than the preset threshold, this heating source may be defined as the primary heating source, otherwise, it is defined as one of rest of the heating sources. For example, a CPU and a GPU in the server are the primary heating sources, while other components are rest of the heating sources. Furthermore, different heat dissipation modes may be adopted according to the classified primary heating sources and rest of the heating sources.

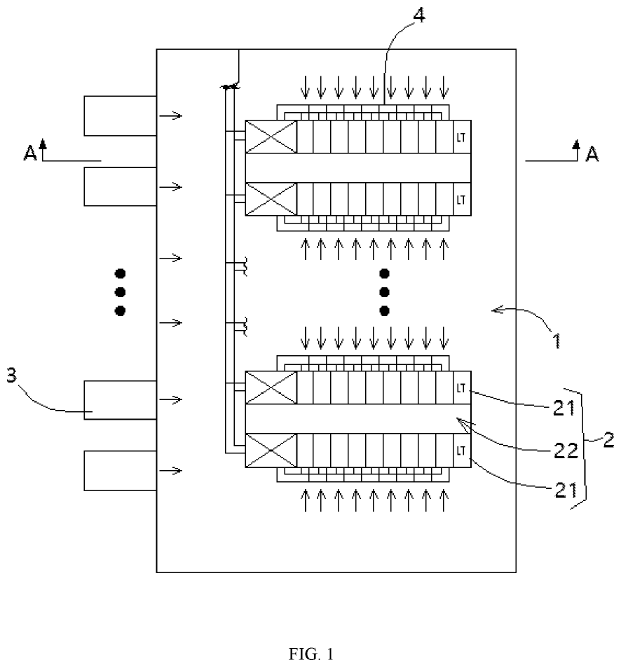

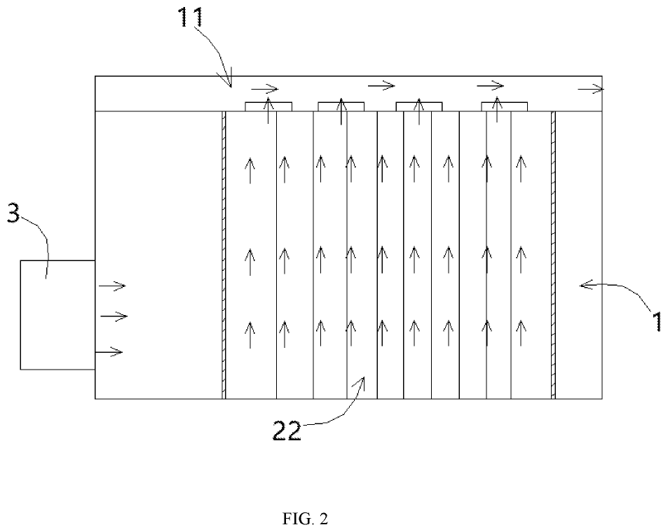

In an implementable embodiment, as shown in FIGS. 1 to 3, a classified heat dissipation system may at least include an accommodating area 1, a group to be heat dissipated 2, an air cooling device 3 and a liquid cooling device 4, where a top end of the accommodating area 1 is provided with a thermal sandwich channel 11, and the accommodating area 1 is not directly communicated with the thermal sandwich channel 11. The device group 21 has rest of heating sources and a plurality of primary heating sources. The group to be heat dissipated 2 is installed in the accommodating area 1, the group to be heat dissipated 2 comprises at least two device groups 21, a thermal channel 22 is surrounded between the at least two device groups 21, and the thermal channel 22 is communicated with the thermal sandwich channel 11. When the air cooling device 3 conveys cold air into the accommodating area 1, the cold air may enter the thermal sandwich channel 11 through the device group 21 and the thermal channel 22 in turn to exchange heat for the device groups 21 (including the primary heating sources and rest of the heating sources). The liquid cooling device 4 is in contact with the plurality of primary heating sources to dissipate heat from the plurality of primary heating sources.

It is pointed out that the above-mentioned air cooling device 3 may employ an air-cooled air conditioner to blow cold air into the accommodating area 1, and the corresponding thermal sandwich channel 11 communicates with the outside, thereby forming an air circulation. Of course, the above-mentioned air cooling device 3 may also employ an indirect evaporative cooling unit. An air outlet of internal circulation of the indirect evaporative cooling unit blows air into the accommodating area 1, and an air inlet of the internal circulation communicates with the thermal sandwich channel 11 for air supply. Thus, the air in the accommodating area 1 is not communicated with the outside and constitutes an air circulation separately, thereby avoiding adverse effects of external air pollution on internal devices.

In practical application, the technicians may classify the heating sources of the device group 21 in advance, to obtain the primary heating sources and rest of the heating sources. Next, the liquid cooling device 4 touches and connects the primary heating sources, such that the liquid cooling device 4 separately dissipates heat from the primary heating sources. The air cooling device 3 simultaneously dissipates heat from the primary heating sources and rest of the heating sources.

As for the above-mentioned at least two device groups 21 surrounding the thermal channel 22, three device groups 21 may be connected end to end to form a triangular thermal channel 22, or four device groups 21 may be connected end to end to form a quadrilateral thermal channel. Number of the device groups 21 is not limited in the present disclosure.

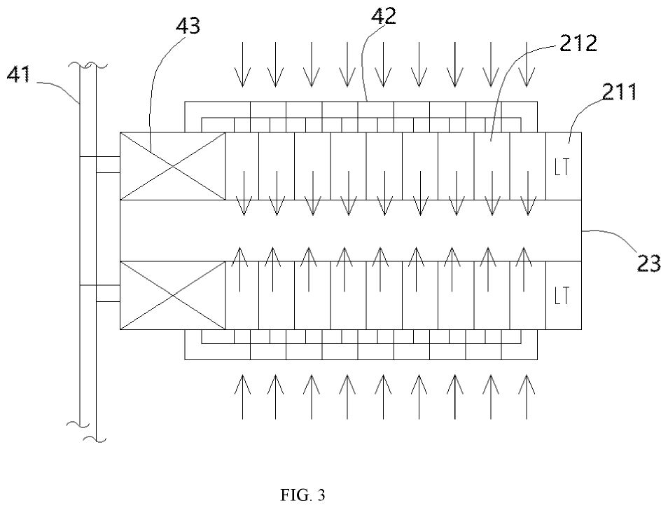

In an implementable embodiment, as shown in FIG. 3, two device groups 21 may also be employed to cooperate with the sealing plate 23 to surround and form the thermal channel 22. Specifically, there may be two device groups 21, and the two device groups 21 are arranged in parallel at intervals. The group to be heat dissipated 2 further comprises two sealing plates 23, where the two sealing plates 23 are respectively positioned at two ends spaced between the two device groups 21, and the two sealing plates 23 and the two device groups 21 surround to form the thermal channel 22.

Further, the air cooling device 3 may be connected to one side of the accommodating area 1. There may be a plurality of air cooling devices 3, and the plurality of air cooling devices 3 are arranged at intervals along a length direction of the accommodating area 1. There are a plurality of groups to be heat dissipated 2, and the plurality of groups to be heat dissipated 2 are arranged at intervals along the length direction of the accommodating area 1. Thus, an air blowing direction of the air cooling device 3 faces a gap between two adjacent groups to be heat dissipated 2, such that the air from the air cooling device 3 may enter into the groups to be heat dissipated 2 from two sides, thereby avoiding a problem of uneven heat dissipation, which is caused by the air from the air cooling device 3 only entering from the device group 21 on one side of the group to be heat dissipated 2.

The present disclosure also provides two implementable embodiments with respect to the specific structure of the liquid cooling device 4.

In one implementable embodiment, the liquid cooling device 4 comprises a first circulation loop (not shown) and a plurality of heat conductive components 5. A cooling tower is connected in series with the first circulation loop, and the cooling tower is configured to dissipate heat from liquid in the first circulation loop, such that the hot liquid is changed into a cold liquid. One end of each of the plurality of heat conductive components 5 is connected in series with the first circulation loop, and the plurality of heat conductive components 5 are connected in parallel with each other. Other ends of the plurality of heat conductive components 5 are respectively in contact with the plurality of primary heating sources, to exchange heat from the plurality of primary heating sources with the liquid in the first circulation loop through the plurality of heat conductive components 5.

In actual use, the first circulation loop may be a circulation loop comprising a water inlet pipeline and a water outlet pipeline, and the cooling tower is configured to cool hot water discharged from the water outlet pipeline, such that cold water after cooling is discharged through the water inlet pipeline. Thus, the discharged cold water flows through one end of the heat conductive component 5, and the other end of the heat conductive component 5 is in contact with the primary heating source for heat conduction, so the discharged cold water is heat-exchanged and becomes hot water at one end of the heat conductive component 5, and then is recirculated into the cooling tower through the water outlet pipeline for sequential circulation.

It should be pointed out that reference may be made to the prior art for the specific structure of the cooling tower in the present disclosure, which is not to be described in detail here.

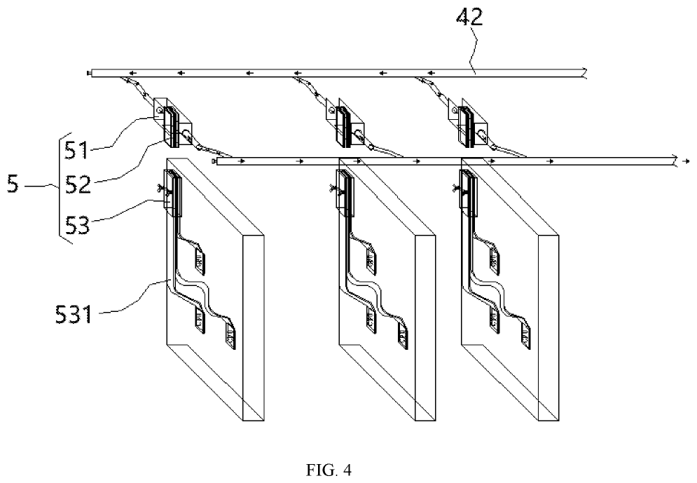

In another implementable embodiment, as shown in FIG. 3 and FIG. 4, the liquid cooling device 4 may include an external circulation loop 41, an internal circulation loop 42, a heat exchange unit 43, and a plurality of heat conductive components 5. An outer flow passage of the heat exchange unit 43 is connected in series with the external circulation loop 41, an inner flow passage of the heat exchange unit 43 is connected in series with the internal circulation loop 42, and a cooling tower is connected in series with the external circulation loop 41, such that liquid in the external circulation loop 41 exchanges heat with liquid in the internal circulation loop 42. One end of each of the plurality of heat conductive components 5 is connected in series with the internal circulation loop 42, and the plurality of heat conductive components 5 are connected in parallel with each other. Other ends of the plurality of heat conductive components 5 are respectively in contact with the plurality of primary heating sources, to exchange heat from the plurality of primary heating sources with the liquid in the internal circulation loop 42 through the plurality of heat conductive components 5.

In practical application, the heat exchange unit 43 may employ a plate heat exchanger, and the corresponding plate heat exchanger is provided with an internal circulation flow passage and an external circulation flow passage, such that the circulating liquid in the external circulation loop 41 does not touch the circulating liquid in the internal circulation loop 42, thereby preventing doped impurities in the liquid in the external circulation loop 41 from adversely affecting the internal circulation loop 42, for example, causing blockage and adverse effects of heat dissipation by inner wall adhesion.

The specific structure of the heat conductive component 5 is properly selected to facilitate the installation of the internal circulation loop 42, to reduce liquid leakage, and to effectively dissipate heat from the primary heating sources. In one implementable embodiment, as shown in FIG. 4, the heat conductive component 5 includes a heat exchange box 51, a male contact head 52, and a female contact head 53. The male contact head 52 is connected to the heat exchange box 51, and one end of the male contact head 52 is positioned in an internal cavity of the heat exchange box 51. One end of the female contact head 53 is detachably connected to other end of the male contact head 52, and other end of the female contact head 53 is in contact with the primary heating source. The circulating liquid in the internal circulation loop 42 flows through the internal cavity of the heat exchange box 51 and exchanges heat with the primary heating source through the male contact head 52 and the female contact head 53. In this way, the internal circulation loop is directly guided to a server cabinet, such that a liquid sealing structure is not needed, so installation is more convenient and quick, and the manufacturing costs are reduced.

Further, a plurality of heat conductive bars 531 are provided at the other end of the female contact head 53, and the plurality of heat conductive bars 531 are respectively connected to the primary heating sources, such that one heat conductive component 5 can exchange heat with a plurality of primary heating sources. The heat conductive bars 531 may be made of flexible heat conductive materials, such that the heat conductive bars 531 may be bent towards the primary heating sources in different directions, to facilitate installation and use.

Based on the same inventive concept, the present disclosure also provides a data center, which comprises at least a plurality of computer rooms, each of the plurality of computer rooms is provided with the classified heat dissipation system, where the accommodating area 1 is the computer room.

Correspondingly the device group 21 may include an array cabinet 211 and a plurality of servers 212. The plurality of servers 212 are arranged side by side, and the array cabinet 211 and the heat exchange unit 43 are respectively positioned at two ends of each of the plurality of servers 212, such that a power supply device and the liquid cooling device are distributed at the two ends, which can effectively reduce adverse effects of accidental liquid leakage on power supply.

It should be pointed out that reference may be made to the above contents for the structure of the classified heat dissipation system in the data center, which is not to be described in detail here.

As can be seen, according to the technical solutions provided by the present disclosure, a group to be heat dissipated is arranged in the accommodating area, where the group to be heat dissipated comprises a plurality of device groups, and the plurality of device groups can surround and form a thermal channel. The thermal channel is communicated with the thermal sandwich channel positioned at the top end of the accommodating area. When the air cooling device blows cold air into the accommodating area to dissipate heat, gas in the accommodating area may flow out through the device group, the thermal channel and the thermal sandwich channel in turn, thus exchanging heat through the plurality of device groups. Meanwhile, the heating sources above the device group are classified into the primary heating sources and rest of heating sources according to calorific capacity, and the liquid cooling device is in contact with the primary heating sources, to carry out liquid cooling and dissipate heat from the primary heating sources. In this way, liquid cooling and air cooling are selected for heat dissipation or only the air cooling is selected for heat dissipation according to heat dissipation requirements of each heating source above the device group, to implement classified heat dissipation and effectively meet the heat dissipation requirements.

The examples set forth above are only illustrated as preferred examples of the present disclosure, and are not intended to limit the present disclosure. All modifications, equivalent substitutions and improvements made within the spirit and principles of the present disclosure shall fall within the protection scope of the present disclosure.

What is claimed is:

1. A classified heat dissipation system, at least comprising an accommodating area (1), a group to be heat dissipated (2), an air cooling device (3) and a liquid cooling device (4), wherein a top end of the accommodating area (1) is provided with a thermal sandwich channel (11);
the group to be heat dissipated (2) is installed in the accommodating area (1), the group to be heat dissipated (2) comprises at least two device groups (21), a thermal channel (22) is surrounded between the at least two device groups (21), and the thermal channel (22) is communicated with the thermal sandwich channel (11), wherein each of the at least two device groups (21) has rest of heating sources and a plurality of primary heating sources;
the air cooling device (3) conveys cold air into the accommodating area (1), and the cold air enters the thermal sandwich channel (11) through the device group (21) and the thermal channel (22) to dissipate heat from the plurality of primary heating sources and the rest of heating sources; and
the liquid cooling device (4) is in contact with the plurality of primary heating sources to dissipate heat from the plurality of primary heating sources.

2. The classified heat dissipation system according to claim 1, wherein number of the device groups (21) is two, and the two device groups (21) are arranged in parallel at intervals; and
the group to be heat dissipated (2) further comprises two sealing plates (23), the two sealing plates (23) are respectively positioned at two ends spaced between the two device groups (21), and the two sealing plates (23) and the two device groups (21) surround to form the thermal channel (22).

3. The classified heat dissipation system according to claim 2, wherein the air cooling device (3) is connected to one side of the accommodating area (1), there are a plurality of the air cooling devices (3), and the plurality of air cooling devices (3) are arranged at intervals along a length direction of the accommodating area (1).

4. The classified heat dissipation system according to claim 3, wherein there are a plurality of the groups to be heat dissipated (2), and the plurality of groups to be heat dissipated (2) are arranged at intervals along the length direction of the accommodating area (1).

5. The classified heat dissipation system according to claim 4, wherein the liquid cooling device (4) comprises a first circulation loop and a plurality of heat conductive components (5);
a cooling tower is connected in series with the first circulation loop, and the cooling tower is configured to exchange heat with liquid in the first circulation loop;
one end of each of the plurality of heat conductive components (5) is connected in series with the first circulation loop, and the plurality of heat conductive components (5) are connected in parallel with each other; and
other ends of the plurality of heat conductive components (5) are respectively in contact with the plurality of primary heating sources, to exchange heat from the plurality of primary heating sources with the liquid in the first circulation loop through the plurality of heat conductive components (5).

6. The classified heat dissipation system according to claim 4, wherein the liquid cooling device (4) comprises an external circulation loop (41), an internal circulation loop (42), a heat exchange unit (43), and a plurality of heat conductive components (5);
an outer flow passage of the heat exchange unit (43) is connected in series with the external circulation loop (41), an inner flow passage of the heat exchange unit (43) is connected in series with the internal circulation loop (42), and a cooling tower is connected in series with the external circulation loop (41), such that liquid in the external circulation loop (41) exchanges heat with liquid in the internal circulation loop (42);
one end of each of the plurality of heat conductive components (5) is connected in series with the internal circulation loop (42), and the plurality of heat conductive components (5) are connected in parallel with each other; and
other ends of the plurality of heat conductive components (5) are respectively in contact with the plurality of primary heating sources, to exchange heat from the plurality of primary heating sources with the liquid in the internal circulation loop (42) through the plurality of heat conductive components (5).

7. The classified heat dissipation system according to claim 6, wherein the heat conductive component (5) comprises a heat exchange box (51), a male contact head (52), and a female contact head (53);
the male contact head (52) is connected to the heat exchange box (51), and one end of the male contact head (52) is positioned in an internal cavity of the heat exchange box (51); and
one end of the female contact head (53) is detachably connected to other end of the male contact head (52), and other end of the female contact head (53) is in contact with the primary heating source; and
circulating liquid in the internal circulation loop (42) flows through the internal cavity of the heat exchange box (51) and exchanges heat with the primary heating source through the male contact head (52) and the female contact head (53).

8. The classified heat dissipation system according to claim 7, wherein the other end of the female contact head (53) is provided with a plurality of heat conductive bars (531), and the plurality of heat conductive bars (531) are respectively connected to the plurality of primary heating sources.

9. A data center comprising at least a plurality of computer rooms, each of the plurality of computer rooms being provided with the classified heat dissipation system, wherein the classified heat dissipation system, at least comprising an accommodating area (1), a group to be heat dissipated (2), an air cooling device (3) and a liquid cooling device (4), wherein a top end of the accommodating area (1) is provided with a thermal sandwich channel (11);
the group to be heat dissipated (2) is installed in the accommodating area (1), the group to be heat dissipated (2) comprises at least two device groups (21), a thermal channel (22) is surrounded between the at least two device groups (21), and the thermal channel (22) is communicated with the thermal sandwich channel (11), wherein each of the at least two device groups (21) has rest of heating sources and a plurality of primary heating sources;
the air cooling device (3) conveys cold air into the accommodating area (1), and the cold air enters the thermal sandwich channel (11) through the device group (21) and the thermal channel (22) to dissipate heat from the plurality of primary heating sources and the rest of heating sources; and
the liquid cooling device (4) is in contact with the plurality of primary heating sources to dissipate heat from the plurality of primary heating sources.

10. The data center according to claim 9, wherein number of the device groups (21) is two, and the two device groups (21) are arranged in parallel at intervals; and
the group to be heat dissipated (2) further comprises two sealing plates (23), the two sealing plates (23) are respectively positioned at two ends spaced between the two device groups (21), and the two sealing plates (23) and the two device groups (21) surround to form the thermal channel (22).

11. The data center according to claim 10, wherein the air cooling device (3) is connected to one side of the accommodating area (1), there are a plurality of the air cooling devices (3), and the plurality of air cooling devices (3) are arranged at intervals along a length direction of the accommodating area (1).

12. The data center according to claim 11, wherein there are a plurality of the groups to be heat dissipated (2), and the plurality of groups to be heat dissipated (2) are arranged at intervals along the length direction of the accommodating area (1).

13. The data center according to claim 12, wherein the liquid cooling device (4) comprises a first circulation loop and a plurality of heat conductive components (5);
a cooling tower is connected in series with the first circulation loop, and the cooling tower is configured to exchange heat with liquid in the first circulation loop;
one end of each of the plurality of heat conductive components (5) is connected in series with the first circulation loop, and the plurality of heat conductive components (5) are connected in parallel with each other; and
other ends of the plurality of heat conductive components (5) are respectively in contact with the plurality of primary heating sources, to exchange heat from the plurality of primary heating sources with the liquid in the first circulation loop through the plurality of heat conductive components (5).

14. The data center according to claim 12, wherein the liquid cooling device (4) comprises an external circulation loop (41), an internal circulation loop (42), a heat exchange unit (43), and a plurality of heat conductive components (5);
an outer flow passage of the heat exchange unit (43) is connected in series with the external circulation loop (41), an inner flow passage of the heat exchange unit (43) is connected in series with the internal circulation loop (42), and a cooling tower is connected in series with the external circulation loop (41), such that liquid in the external circulation loop (41) exchanges heat with liquid in the internal circulation loop (42);
one end of each of the plurality of heat conductive components (5) is connected in series with the internal circulation loop (42), and the plurality of heat conductive components (5) are connected in parallel with each other; and
other ends of the plurality of heat conductive components (5) are respectively in contact with the plurality of primary heating sources, to exchange heat from the plurality of primary heating sources with the liquid in the internal circulation loop (42) through the plurality of heat conductive components (5).

15. The data center according to claim 14, wherein the heat conductive component (5) comprises a heat exchange box (51), a male contact head (52), and a female contact head (53);
the male contact head (52) is connected to the heat exchange box (51), and one end of the male contact head (52) is positioned in an internal cavity of the heat exchange box (51); and
one end of the female contact head (53) is detachably connected to other end of the male contact head (52), and other end of the female contact head (53) is in contact with the primary heating source; and
circulating liquid in the internal circulation loop (42) flows through the internal cavity of the heat exchange box (51) and exchanges heat with the primary heating source through the male contact head (52) and the female contact head (53).

16. The data center according to claim 15, wherein the other end of the female contact head (53) is provided with a plurality of heat conductive bars (531), and the plurality of heat conductive bars (531) are respectively connected to the plurality of primary heating sources.
